(19) United States
(12) Patent Application Publication
(10) Pub. No.: US 2011/0073178 A1
(43) Pub. Date: Mar. 31, 2011

(54) ELECTRICALLY CONDUCTIVE PASTE, SOLAR CELL CONTAINING SAME AND METHOD

(75) Inventors: Weihua TAN, Shenzhen (CN); Zhen Liu, Shenzhen (CN); Yong Zhou, Shenzhen (CN); Zhanfeng Jiang, Shenzhen (CN)

(73) Assignee: BYD Co. Ltd, Shenzhen (CN)

(21) Appl. No.: 12/888,195

(22) Filed: Sep. 22, 2010

(30) Foreign Application Priority Data
Sep. 30, 2009 (CN) 200910190565.X

(51) Int. Cl. H01L 31/0216; H01B 1/02

(52) U.S. Cl. 136/256; 252/512; 252/514

(57) ABSTRACT

An electrically conductive paste for a solar cell comprises a metal powder, an inorganic adhesive, an aqueous adhesive and an auxiliary agent. The aqueous adhesive comprises a water-soluble polymer.

### CROSS-REFERENCE TO RELATED APPLICATION

The present application claims priority to and the benefit of Chinese Patent Application No. 200910190565.X, filed with the State Intellectual Property Office of the People's Republic of China (SIPO) on Sep. 30, 2009, the entire content of which is hereby incorporated by reference.

### FIELD

The disclosure relates to a solar cell, more particularly to an electrically conductive paste for a solar cell, and a method for preparing the same.

### BACKGROUND

Solar energy has been widely used. Silicon-based solar cells are usually made by printing an electrically conductive paste onto a silicon substrate, drying and firing the paste. Conductive pastes have a great impact on the performance of solar cells. At present, organic solvent carrier systems have been widely used for preparing conductive pastes. Nevertheless, the organic solvent may cause environmental pollutions and be harmful to human body. Furthermore, the cost of the organic solvent is relatively high.

### SUMMARY

In one aspect, an electrically conductive paste for a solar cell comprises a metal powder, an inorganic adhesive, an aqueous adhesive and an auxiliary agent. The aqueous adhesive comprises a water-soluble polymer.

In another aspect, a solar cell comprises a silicon substrate and an electrically conductive material on the surface of the silicon substrate. The electrically conductive material comprises a paste. The paste comprises a metal powder, an inorganic adhesive, an aqueous adhesive, and an auxiliary agent. The aqueous adhesive comprises a water-soluble polymer.

In yet another aspect, a method of preparing an electrically conductive paste, comprising the steps of: mixing a water-soluble polymer with water to provide an aqueous adhesive; and mixing the aqueous adhesive with an inorganic adhesive, a metal powder and an auxiliary agent to provide an electrically conductive paste.

### DETAILED DESCRIPTION

It will be appreciated by those of ordinary skill in the art that the disclosure may be embodied in other specific forms without departing from the spirit or essential character thereof. The presently disclosed embodiments are therefore considered in all respects to be illustrative and not restrictive.

An electrically conductive paste for solar cells comprises a metal powder, an inorganic adhesive, an aqueous adhesive that includes a water-soluble polymer, and an auxiliary agent. In one embodiment, based on the total weight of the conductive paste, the amount of the metal powder is from about 60 wt % to about 85 wt %, the amount of the inorganic adhesive is from about 0.5 wt % to about 10 wt %, the amount of the aqueous adhesive is from about 10 wt % to about 30 wt %, and the amount of the auxiliary agent is from about 0.05 wt % to about 5 wt %.

In some embodiments, the water-soluble polymer is selected from the group consisting of cellulose ethers, poly(acrylic acid), poly(methacrylic acid), acrylic-methacrylic copolymers, polyvinyl alcohol, polyethylene glycol, polyacrylamide, polyethylene oxide, water-soluble polyurethane resins, starch derivatives, polyvinylpyrrolidone, and combinations thereof. In one instance, the starch derivative is selected from the group consisting of sodium carboxymethyl starch, pregelatinized starches, modified hydroxyethyl starches, quaternary ammonium cation starches, amphoteric starches, and combinations thereof. In another instance, the cellulose ether is selected from the group consisting of sodium carboxymethylcellulose, hydroxypropyl methylcellulose, hydroxyethylcellulose, methylcellulose, and combinations thereof.

In some embodiments, the concentration of the water-soluble polymer can be from about 0.1 wt % to about 20 wt %, based on the total weight of the aqueous adhesive. In one example, it can be about 0.5 wt % to about 8 wt %.

In one embodiment, the auxiliary agent is selected from the group consisting of an anti-sedimentation agent, a surfactant, a water-soluble rheology control agent, and combinations thereof. In the present disclosure, the auxiliary agent may enhance the structure of the conductive paste and provide a good appearance of the silicon film of solar cells.

In one embodiment, the anti-sedimentation agent is selected from the group consisting of hydrophilic fumed silica, organobentonite, diatomite, and combinations thereof. The anti-sedimentation agent may avoid the sedimentation of the conductive paste.

In another embodiment, the surfactant is a fluorocarbon surfactant. For example, commercially available Fluorad FC-4430, FC-4432, or Zonyl® FSJ can be used.

In yet another embodiment, the water-soluble rheology control agent is selected from the group consisting of ammonium sulfate, terephthalic acid, furoic acids, and combinations thereof.

In some embodiments, the metal powder is selected from the group consisting of silver powders, aluminum powders, silver coated copper powders, silver coated aluminum powders, and combinations thereof. They can be spherical or flake shape. Preferably, the metal powder has a D50 value of about 0.25 μm to about 8 μm. The value of D50 is the smallest sieve opening through which 50% of the powder passes. More preferably, the D50 value is from about 0.25 μm to about 3 μm.

In some embodiments, the inorganic adhesive is a non-lead glass powder. Preferably, the non-lead glass powder is made from an oxide powder. Preferably, the oxide powder comprises at least two oxides selected from the group consisting of lead oxide, bismuth oxide, boron trioxide, silicon dioxide, calcium oxide, aluminum oxide, zinc oxide, cobalt oxide, magnesium oxide, zirconium oxide, and strontium oxide. Preferably, the oxide powder has a D50 value of from about 0.5 μm to about 8 μm.

A method of preparing an electrically conductive paste comprises the steps of: mixing a water-soluble polymer with water to provide an aqueous adhesive; and mixing an inorganic adhesive, a metal powder and an auxiliary to the aqueous adhesive to provide an electrically conductive paste. Preferably, the method further comprises a step of grinding the electrically conductive paste.

Preferably, the water-soluble polymer is selected from the group consisting of cellulose ethers, poly(acrylic acid), poly(methacrylic acid), acrylic-methacrylic copolymers, polyvinyl alcohol, polyethylene glycol, polyacrylamide, polyethylene oxide, aqueous polyurethane resins, starch derivatives, polyvinylpyrrolidone, and combinations thereof.

In some embodiments, the method comprises the following steps.

(1) A water-soluble polymer is dissolved in de-ionized water to obtain a mixture. The mixture is heated to about 70° C. and stirred uniformly to obtain an aqueous adhesive.

(2) The aqueous adhesive and an inorganic adhesive are stirred uniformly in the stainless tank of a high-speed dispersing machine. A metal powder is added into the tank in two or three portions. An auxiliary agent is added into the tank and the mixture is stirred for 30 to 60 minutes to provide a uniform mixture.

(3) The obtained mixture is grinded by a three-roller mill (Ø150) for 10-15 times to obtain a conductive paste for solar cells.

Hereinafter, the invention will be described in details with reference to the following embodiments.

### Embodiment 1

### (1) Preparation of an Aqueous Adhesive

Sodium carboxymethylcellulose (CMC) is dissolved in de-ionized water to obtain a mixture. The weight ratio of the sodium carboxymethylcellulose to the water is about (2:98). The mixture is heated to about 70° C. and stirred uniformly to obtain the aqueous adhesive A1.

### (2) Preparation of an Inorganic Adhesive

Bismuth oxide, boron trioxide, silicon dioxide, zinc oxide and aluminum oxide are mixed in a V-type mixer for about 20 minutes to obtain a mixed oxide powder. The weight ratio of the bismuth oxide: boron trioxide:silicon dioxide:zinc oxide:aluminum oxide is about 65:20:8:6:1. The mixed oxide powder is placed in an oven at about 500° C. for 0.5 hour. Then the temperature is increased to 1250° C. and maintained for 1 hour. Then the mixed oxide powder is quenched by water and dried until the water content is less than 8%. The obtained mixture is crushed by a crusher, and then is ball-milled at a speed of 100 r/minute for about 48 hours. The weight ratio of the mill balls (zirconia ball):the mixture:de-ionized water is about 2:1:0.5. The mixture is filtered and dried to obtain a glass powder with D₅₀ of about 3.5 μm.

### (3) Preparation of a Conductive Paste

The aqueous adhesive A1 and the glass powder are stirred in a stainless tank of a high-speed dispersing machine for 30 minutes at 500 r/minute. A spherical aluminum powder (Yuanyang Co., HeNan, China; D₅₀=3 μm) is added into the tank in two portions and the mixture is stirred for 60 minutes. A fluorocarbon surfactant Fluorad FC-4430 (3M Co.) and hydrophilic fumed silica are added into the tank and stirred at 1500 r/minute for 30 minutes. The weight ratio of the aqueous adhesive A1:glass powder:aluminum powder:fluorocarbon surfactant:hydrophilic fumed silica is about 23:2.5:74.1:0.1:0.3. The obtained mixture is milled by a three-roller mill (Ø150) for 10 times to obtain the conductive paste S1 for solar cells. The fineness of the paste is less than 25 μm, measured by a fineness gauge.

### Embodiment 2

### (1) Preparation of an Aqueous Adhesive

Sodium carboxymethylcellulose (CMC) is dissolved in de-ionized water to obtain a mixture. The weight ratio of the sodium carboxymethylcellulose to the water is about 5:95. The mixture is heated to about 70° C. and stirred uniformly to obtain the aqueous adhesive A2.

### (2) Preparation of an Inorganic Adhesive

Lead oxide, boron trioxide, silicon dioxide, zinc oxide, aluminum oxide and cobalt oxide are mixed by a V-type mixer for about 20 minutes to obtain a mixed oxide powder. The weight ratio of the lead oxide:boron trioxide:silicon dioxide:zinc oxide:aluminum oxide:cobalt oxide is about 65:13:9:4.5:8:0.5. The mixed oxide powder is placed in an oven at 500° C. for 0.5 hour. The temperature is increased to 1300° C. and maintained for 1 hour. The mixed oxide powder is quenched by water and dried until the water content is less than 6%. The obtained mixture is crushed by a crusher, and then is ball-milled at 150 r/minute for about 48 hours. The weight ratio of the mill balls (zirconia ball):mixture:de-ionized water is about 2:1.5:0.5. The mixture is filtered and dried to obtain a glass powder with D₅₀ of about 2.5 μm.

### (3) Preparation of a Conductive Paste

The aqueous adhesive A2 and the glass powder are stirred in a stainless tank of a high-speed dispersing machine for 30 minutes at 500 r/minute. A flake silver powder (Kunming Research Institute of Precious Metals, China; D₅₀=2-3 μm) is added into the tank in two portions and the mixture is stirred for 60 minutes. A fluorocarbon surfactant Fluorad FC-4430 (3M Co.) and organobentonite are added into the tank and the mixture is stirred at 1500 r/minute for 30 minutes. The weight ratio of the aqueous adhesive A2:glass powder:silver powder:fluorocarbon surfactant:organobentonite is about 18.5:5:76.2:0.1:0.2. The obtained mixture is milled by a three-roller mill (Ø150) for 12 times to obtain the conductive paste S2 for solar cells. The fineness of the paste is less than 15 μm, measured by a fineness gauge.

### Embodiment 3

### (1) Preparation of an Aqueous Adhesive

A hydroxyethylcellulose (HEC) is dissolved in de-ionized water to obtain a mixture. The weight ratio of the sodium carboxymethylcellulose to the water is about 6:94. The mixture is heated to about 75° C. and stirred uniformly to obtain the aqueous adhesive A3.

### (2) Preparation of an Inorganic Adhesive

Lead oxide, boron trioxide, silicon dioxide and zinc oxide are placed in a V-type mixer for about 60 minutes to obtain a mixed oxide powder. The weight ratio of the lead oxide:boron trioxide:silicon dioxide:zinc oxide is about 78:8:8:6.

### (3) Preparation of a Conductive Paste

The aqueous adhesive A3 and the mixed oxide powder are placed into a stainless tank of a high-speed dispersing machine and stirred for 30 minutes at 500 r/minute. A spherical silver powder (Kunming Research Institute of Precious Metals, China; D₅₀=2-3 μm) is added into the tank in two portions and the mixture is stirred for 60 minutes. A fluorocarbon surfactant Fluorad FC-4430 (3M Co.), a water-soluble rheology control agent containing ammonium sulfate powders and hydrophilic fumed silica are added into the tank and stirred at 1500 r/min for 30 minutes. The weight ratio of the aqueous adhesive A3:mixed oxide powder:silver powder:fluorocarbon surfactant:ammonium sulfate powder: hydrophilic fumed silica is about 18.8:5.2:75.5:0.1:0.2:0.2. The obtained mixture is milled by a three-roller mill (Ø150) for 12 times to obtain the conductive paste S3 for solar cells. Its fineness is less than 15 μm, measured by a fineness gauge.

### Embodiment 4

The EMBODIMENT 4 is substantially similar to EMBODIMENT 3, with the exception that the sodium carboxymethyl starch (CMS) is used instead of the hydroxyethylcellulose (HEC) in step (1).

The conductive paste is S4.

Testing

(1) Viscosity of Conductive Paste

Using the method of GB/T17473.5-1998, the viscosities of conductive pastes S1-S4 are tested at 25° C. by NDJ-79 Rotary Viscometer at 75 rad/minute. The results are recorded in Table 1.

(2) Storage Stability of Conductive Pastes

The conductive pastes S1-S4 are storage at 25° C. in a closed container for 3 months. Their viscosities are tested. They are observed whether any settlement has occurred. The results are recorded in Table 1.

(3) Retention of Pastes on a Mesh Screen

The conductive pastes S1-S4 are disposed onto a 280 mesh metal screen for about 2 hours, with a thickness of about 5 to 8 mm. The paste that passes through the mesh screen is weighted. The weight of less than 5 g is considered as no leaking. The weight of between 5 g to 15 g is considered as slight leaking. The weight of more than 15 g is considered as severe leaking. The results are recorded in Table 1.

(4) Appearance and Adhesion Force of Pastes

The conductive pastes S1-S4 are screen printed onto an aluminum film. Then, the film is heated. They are observed by naked eye to determine whether there are any dents, wrinkles, peeling, ripples and other undesired appearances.

The heated aluminum films are immersed into water at 25° C. for 7 days. They are observed by naked eye to determine whether the pastes are peeling off.

The results are recorded in Table 1.

(5) Photoelectric Conversion Efficiency

The conductive pastes S1-S4 are used on monocrystalline silicon wafers. The monocrystalline silicon wafer has a size of about 125×125 mm, a thickness of about 200 μm before the corrosion, and a thickness of about 180 μm before the printing. The mesh has about 280 mesh for aluminum pastes and about 325 mesh for silver pastes. The weight of the aluminum paste coated on the back surface of the silicon wafer is about 1.0 g. The weight of the silver paste on the back surface of the silicon wafer is about 0.10 g. The weight of the silver paste on the light-receiving surface of the silicon wafer is about 0.15 g. The printed wafer is dried at a temperature of about 70 to 100° C. After the light-receiving surface is printed, the monocrystalline silicon wafer is fired in a tunnel furnace at a temperature of about 810 to 930° C. The temperature is distributed in a gradient. The firing time is about 2 minutes, and the time at the peak firing temperature is about 2 seconds.

When preparing the solar cell, the present pastes S1-S4 are used on one surface of the silicon wafer. Pastes on the other surfaces of the silicon wafer are selected from the products of Ferro Co. For example, #53102 aluminum paste, #3347 silver paste for the back-surface, and #33462 silver paste for the light-receiving surface are used.

The photoelectric conversion efficiency of the solar cell wafers is measured by a single-flash simulator. The testing conditions include a light intensity of about 1000 W/m², a spectrum Am1.5 and a temperature of about 25° C.

The results are recorded in Table 1.

TABLE 1

| | | Viscosity | Retention | Appearance; | |
|---|---|---|---|---|---|
| | Viscos- | after 3 | of Pastes | Adhesion | Photoelectric |
| | ity | Months (mPas); | on Mesh | Force of | Conversion |
| | (mPas) | Storage Stability | Screens | Coating | Efficiency |
| S1 | 38000 | 54000; no | no leaking | Good | 17.87% |
| | | settlement | | appearance; | |
| | | | | no peeling | |
| | | | | off | |
| S2 | 68000 | 87000; no | no leaking | Good | 17.84% |
| | | settlement | | appearance; | |
| | | | | no peeling | |
| | | | | off | |
| S3 | 72000 | 89000; no | no leaking | Good | 17.85% |
| | | settlement | | appearance; | |
| | | | | no peeling | |
| | | | | off | |
| S4 | 85000 | 98000; no | no leaking | Good | 17.83% |
| | | settlement | | appearance; | |
| | | | | no peeling | |
| | | | | off | |

Many modifications and other embodiments of the present disclosure will come to mind to one skilled in the art to which the present disclosure pertains having the benefit of the teachings presented in the foregoing description. It will be apparent to those skilled in the art that variations and modifications of the present disclosure may be made without departing from the scope or spirit of the present disclosure. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. An electrically conductive paste for a solar cell comprising:
a metal powder;
an inorganic adhesive;
an aqueous adhesive comprising a water-soluble polymer; and
an auxiliary agent.

2. The paste of claim 1, wherein the amount of the metal powder is from about 60 wt % to about 85 wt %, the amount of the inorganic adhesive is from about 0.5 wt % to about 10 wt %, the amount of the aqueous adhesive is from about 10 wt % to about 30 wt %, and the amount of the auxiliary agent is from about 0.05 wt % to about 5 wt %.

3. The paste of claim 1, wherein the water-soluble polymer is selected from the group consisting of cellulose ethers, poly(acrylic acid), poly(methacrylic acid), acrylic-methacrylic copolymers, polyvinyl alcohol, polyethylene glycol, polyacrylamide, polyethylene oxide, water-soluble polyurethane resins, starch derivatives, polyvinylpyrrolidone, and combinations thereof.

4. The paste of claim 3, wherein the cellulose ether is selected from the group consisting of sodium carboxymethylcellulose, hydroxypropyl methylcellulose, hydroxyethylcellulose, methylcellulose, and combinations thereof.

5. The paste of claim 3, wherein the starch derivative is selected from the group consisting of sodium carboxymethyl starch, pregelatinized starches, modified hydroxyethyl starches, quaternary ammonium cation starches, amphoteric starches, and combinations thereof.

6. The paste of claim 1, wherein the concentration of the water-soluble polymer is from about 0.1 wt % to about 20 wt %, based on the total weight of the aqueous adhesive.

7. The paste of claim 1, wherein the auxiliary agent is selected from the group consisting of an anti-sedimentation agent, a surfactant and a water-soluble rheology control agent.

8. The paste of claim 7, wherein the anti-sedimentation agent is selected from the group consisting of hydrophilic fumed silica, organobentonite, diatomite, and combinations thereof.

9. The paste of claim 7, wherein the surfactant is a fluorocarbon surfactant.

10. The paste of claim 7, wherein the water-soluble rheology control agent is selected from the group consisting of ammonium sulfate, terephthalic acid, furoic acids, and combinations thereof.

11. The paste of claim 1, wherein the metal powder are selected from the group consisting of silver powder, aluminum powder, silver coated copper powder, silver coated aluminum powder, and combinations thereof.

12. The paste of claim 1, wherein the metal powder has a D50 value of about 0.2 to about 8 μm.

13. The paste of claim 1, wherein, the inorganic adhesive is a non-lead glass powder.

14. The paste of claim 13, wherein the non-lead glass powder comprises at least two oxides selected from the group consisting of lead oxide, bismuth oxide, boron trioxide, silicon dioxide, calcium oxide, aluminum oxide, zinc oxide, cobalt oxide, magnesium oxide, zirconium oxide, and strontium oxide.

15. The paste of claim 14, wherein the non-lead glass powder comprises boron trioxide, silicon dioxide, and zinc oxide.

16. The paste of claim 14, wherein the non-lead glass powder has a D50 value of about 0.5 to about 8 μm.

17. A solar cell, comprising:
a silicon substrate; and
an electrically conductive material on the surface of the silicon substrate;
wherein the electrically conductive material comprises a paste comprising:
a metal powder;
an inorganic adhesive;
an aqueous adhesive comprising a water-soluble polymer; and
an auxiliary agent.

18. The solar cell of claim 17, wherein the water-soluble polymer is selected from the group consisting of cellulose ethers, poly(acrylic acid), poly(methacrylic acid), acrylic-methacrylic copolymers, polyvinyl alcohol, polyethylene glycol, polyacrylamide, polyethylene oxide, water-soluble polyurethane resins, starch derivatives, polyvinylpyrrolidone, and combinations thereof.

19. A method of preparing an electrically conductive paste, comprising the steps of:
mixing a water-soluble polymer with water to provide an aqueous adhesive; and
mixing the aqueous adhesive with an inorganic adhesive, a metal powder and an auxiliary agent to provide an electrically conductive paste.

20. The method of claim 19, further comprising a step of:
grinding the electrically conductive paste.
